(19) United States
(12) Patent Application Publication
(10) Pub. No.: US 2026/0324075 A1
(43) Pub. Date: Oct. 15, 2026

(54) Array Substrate and Manufacturing Method Therefor, and Display Device

(71) Applicants: Nanjing BOE Display Technology CO., LTD., Nanjing,Jiangsu (CN); BOE Technology Group Co., Ltd., Beijing (CN)

(72) Inventors: Xiaochen CUI, Beijing (CN); Haihong WANG, Beijing (CN); Honggang GU, Beijing (CN); Yang LIU, Beijing (CN)

(21) Appl. No.: 18/880,576

(22) PCT Filed: Dec. 22, 2023
(86) PCT No.: PCT/CN2023/140820

§ 371 Date: Jan. 2, 2025

(51) Int. Cl. H10D 86/40; G02F 1/1333; G02F 1/1362; H10D 86/01; H10D 86/60

(52) U.S. Cl. CPC H10D 86/441; G02F 1/133357; G02F 1/136209; G02F 1/136222; H10D 86/0221; H10D 86/60

(57) ABSTRACT

An array substrate, a manufacturing method therefor, and a display device are provided. The array substrate includes a base substrate; multiple first wires (50) and multiple second wires (60) provided on a side of the base substrate, the first wires (50) extending in a first direction, the second wires (60) extending in a second direction, the first wires (50) and the second wires (60) intersecting with each other to define multiple sub-pixels arranged in an array, each sub-pixel including at least one transistor (20), and the first direction and the second direction intersecting with each other; a color filter layer (30) provided on a side of the transistor (20). The color filter layer (30) includes a color filter pattern corresponding to a sub-pixel, and an orthographic projection of the color filter pattern on the base substrate covers an orthographic projection of the transistor (20) on the base substrate.

### CROSS-REFERENCE TO RELATED APPLICATION

The present application is a U.S. National Phase Entry of International Application No. PCT/CN2023/140820 having an international filing date of Dec. 22, 2023, contents of which are incorporated into the present application by reference.

### TECHNICAL FIELD

The present disclosure relates to, but is not limited to, the field of display technologies, and particularly relates to an array substrate and a manufacturing method for the array substrate, and a display device.

### BACKGROUND

A Liquid Crystal Display (LCD) has characteristics, such as small volume, low power consumption, and no radiation, and has been developed rapidly. A liquid crystal display panel includes a Thin Film Transistor (TFT) array substrate and a Color Filter (CF) substrate that are cell aligned. Liquid Crystal (LC) molecules are provided between the array substrate and the color filter substrate. By controlling a second electrode and a first electrode, an electric field for driving the liquid crystal to deflect is formed, thereby implementing gray scale display.

During a cell aligning process of the array substrate and the color filter substrate, when there is an offset between the array substrate and color filter substrate in the cell aligning, it is easy to cause display defects. In addition, when the display device is bent, a spacer located between the array substrate and the color filter substrate is prone to sliding and offset, thereby easily causing light leakage, display abnormality and other defects in the display device.

### SUMMARY

The following is a summary of subject matters described herein in detail. This summary is not intended to limit the protection scope of claims.

In one aspect, an embodiment of the present disclosure provides an array substrate, including: a base substrate; multiple first wires and multiple second wires provided on a side of the base substrate, the first wires extending in a first direction and the second wires extending in a second direction, the first wires and the second wires intersecting with each other to define multiple sub-pixels arranged in an array, each of the sub-pixels including at least one transistor, and the first direction and the second direction intersecting with each other; and a color filter layer, provided on a side of the transistor; the color filter layer including a color filter pattern corresponding to a sub-pixel, and an orthographic projection of the color filter pattern on the base substrate covering an orthographic projection of the transistor on the base substrate.

In an exemplary implementation, in the first direction, a portion of an orthographic projection of the color filter pattern corresponding to one sub-pixel of adjacent sub-pixels on the base substrate falls into an orthographic projection of the other sub-pixel of the adjacent sub-pixels on the base substrate.

In an exemplary implementation, an orthographic projection of a second wire between the adjacent sub-pixels on the base substrate overlaps with orthographic projections of respective color filter patterns of adjacent two sub-pixels on the base substrate.

In an exemplary implementation, an orthographic projection of a center line of the second wire on the base substrate overlaps with an orthographic projection of an overlapping boundary of the respective color filter patterns of the adjacent two sub-pixels on the base substrate.

In an exemplary implementation, a ratio of a distance in the first direction between a center line of the second wire that is perpendicular to the base substrate and an overlapping boundary of the respective color filter patterns of the adjacent two sub-pixels to a length of the second wire in the first direction is greater than 0 and less than or equal to 0.33.

In an exemplary implementation, the color filter pattern corresponding to one sub-pixel of the adjacent sub-pixels is provided with a bump on at least one side in the first direction, and an orthographic projection of the bump on the base substrate is located in an orthographic projection of the other sub-pixel of the adjacent sub-pixels on the base substrate.

In an exemplary implementation, a shape of the bump includes a trapezoid.

In an exemplary implementation, the color filter layer is provided on a side of the transistor close to the base substrate; or, the color filter layer is provided on a side of the transistor away from the base substrate.

In an exemplary implementation, each of the sub-pixels further includes a connection electrode connected with the at least one transistor, a first electrode provided on a side of the connection electrode away from the base substrate, and a contact hole exposing at least a portion of the connection electrode, and the first electrode is connected with the connection electrode through the contact hole. The color filter layer is provided between the first electrode and the connection electrode, the color filter pattern includes a hollowed-out region, and an orthographic projection of the contact hole on the base substrate is located in an orthographic projection of the hollowed-out region on the base substrate.

In an exemplary implementation, the hollowed-out region of the color filter pattern corresponding to one sub-pixel of the adjacent sub-pixels is connected with the color filter pattern corresponding to the other sub-pixel.

In an exemplary implementation, the color filter pattern corresponding to one sub-pixel of the adjacent sub-pixels is provided with a bump on at least one side in the first direction, and the bump protrudes into the hollowed-out region of the color filter pattern corresponding to the other sub-pixel.

In an exemplary implementation, the contact hole of one sub-pixel of the adjacent sub-pixels has a first edge portion and a second edge portion, the first edge portion is adjacent to a bump of the color filter pattern corresponding to the other sub-pixel, and the second edge portion is adjacent to other sides of the hollowed-out region. A distance between the first edge portion and an edge of the bump in the first direction is L1, a minimum perpendicular distance between the second edge portion and the other sides of the hollowed-out region is L2, and the L1 is greater than or equal to the L2.

In an exemplary implementation, a ratio of the L1 to the L2 is less than or equal to 2 and greater than or equal to 1.

In an exemplary implementation, the array substrate further includes a planarization layer provided on a side of the color filter layer close to the first electrode and an insulation layer provided on a side of the planarization layer close to the first electrode. The contact hole at least includes a first via provided in the planarization layer and a second via provided in the insulation layer, an orthographic projection of the first via on the base substrate is located in an orthographic projection of the second via on the base substrate, and the orthographic projection of the second via on the base substrate is located in an orthographic projection of the connection electrode on the base substrate.

In an exemplary implementation, a minimum perpendicular distance between an edge of the orthographic projection of the first via on the base substrate and an edge of the orthographic projection of the second via on the base substrate is L3, and a minimum perpendicular distance between the edge of the orthographic projection of the first via on the base substrate and an edge of the orthographic projection of the connection electrode on the base substrate is L4, and the L4 is greater than the L3.

In an exemplary implementation, a ratio of the L4 to the L3 is less than or equal to 2 and greater than or equal to 1.1.

In an exemplary implementation, the array substrate further includes a second electrode provided on a side of the color filter layer close to the first electrode, and an insulation layer provided on a side of the second electrode close to the first electrode. The first electrode is in direct contact with the insulation layer.

In an exemplary implementation, the array substrate further includes a spacer layer provided on a side of the insulation layer away from the base substrate. The spacer layer is in direct contact with the insulation layer, and an orthographic projection of the first electrode on the base substrate does not overlap with an orthographic projection of the spacer layer on the base substrate.

In an exemplary implementation, a section of the spacer layer in a direction perpendicular to the base substrate includes at least one of a rectangle, a regular trapezoid, and an inverted trapezoid.

In an exemplary implementation, the transistor includes a gate provided on the base substrate, a gate insulation layer provided on a side of the gate away from the base substrate, an active layer provided on a side of the gate insulation layer away from the base substrate, and a first pole and a second pole provided on a side of the active layer away from the base substrate, and the first pole and the second pole are connected by the active layer.

In another aspect, the present disclosure also provides a display device, including the aforementioned array substrate.

In an exemplary implementation, the display device further includes a color filter substrate provided opposite to the array substrate. The color filter substrate includes a black matrix, and an orthographic projection of the black matrix on the base substrate does not overlap with an orthographic projection of at least a portion of the second wire on the base substrate.

In an exemplary implementation, the display device further includes a first spacer layer. A side of the first spacer layer close to the array substrate is connected with the array substrate, and a side of the first spacer layer close to the color filter substrate is connected with the color filter substrate.

In an exemplary implementation, the display device further includes a first spacer layer and a second spacer layer. A side of the first spacer layer close to the array substrate is connected with the array substrate, a side of the first spacer layer away from the array substrate is connected with the second spacer layer, and a side of the second spacer layer away from the array substrate is connected with the color filter substrate. A section of the first spacer layer in a direction perpendicular to the base substrate includes a regular trapezoid, and a section of the second spacer layer in the direction perpendicular to the base substrate includes an inverted trapezoid.

In another aspect, the present disclosure further provides a manufacturing method for an array substrate, including: forming multiple first wires and multiple second wires on a base substrate, the first wires extending in a first direction and the second wires extending in a second direction, the first wires and the second wires intersecting with each other to define multiple sub-pixels arranged in an array, each of the sub-pixels including at least one transistor, and the first direction and the second direction intersecting with each other; and forming a color filter layer on a side of the transistor, the color filter layer including a color filter pattern corresponding to a sub-pixel, and an orthographic projection of the color filter pattern on the base substrate covering an orthographic projection of the transistor on the base substrate.

Other aspects of the present disclosure may be comprehended after the drawings and the detailed description are read and understood.

### BRIEF DESCRIPTION OF DRAWINGS

Accompanying drawings are used to provide understanding of technical solution of the present disclosure, and form a part of the specification. The accompanying drawings and embodiments of the present disclosure are adopted to explain the technical solution of the present disclosure, and do not form limitations on the technical solution of the present disclosure.

FIG. 1 is a schematic sectional view of a structure of a display device.

FIG. 2 is a schematic diagram of a planar structure of a display device.

FIG. 3 is a schematic diagram of a planar structure of an array substrate.

FIG. 4 is a schematic diagram of a planar structure of a display device according to an exemplary embodiment of the present disclosure.

FIG. 5 is a schematic diagram of a planar structure after a first conductive layer is formed in a manufacturing process of an array substrate according to an exemplary embodiment of the present disclosure.

FIGS. 6a and 6b are schematic diagrams of a planar structure after an active layer is formed in a manufacturing process of an array substrate according to an exemplary embodiment of the present disclosure.

FIGS. 7a and 7b are schematic diagrams of a planar structure after a second conductive layer is formed in a manufacturing process of an array substrate according to an exemplary embodiment of the present disclosure.

FIGS. 8a and 8b are schematic diagrams of a planar structure after a color filter layer is formed in a manufacturing process of an array substrate according to an exemplary embodiment of the present disclosure.

FIGS. 9a and 9b are schematic diagrams of a planar structure after a third conductive layer is formed in a manufacturing process of an array substrate according to an exemplary embodiment of the present disclosure.

FIG. 10 is a schematic diagram of a planar structure after a fourth conductive layer is formed in a manufacturing process of an array substrate according to an exemplary embodiment of the present disclosure.

FIG. 11 is a schematic sectional view of a structure of a display device according to an exemplary embodiment of the present disclosure.

FIG. 12 is a schematic sectional view of a structure of a display device according to an exemplary embodiment of the present disclosure.

FIG. 13 is a schematic sectional view of a structure of a display device according to an exemplary embodiment of the present disclosure.

FIG. 14 is a schematic partial planar view of a display device according to an exemplary embodiment of the present disclosure.

FIG. 15 is a schematic sectional view of a structure of a display device according to an exemplary embodiment of the present disclosure.

### DETAILED DESCRIPTION

To make the objectives, technical solutions, and advantages of the present disclosure clearer, embodiments of the present disclosure will be described in detail below with reference to the accompanying drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings. Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, and the like for indicating directional or positional relationships are used to illustrate positional relationships between the constituent elements with reference to the drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements are changed as appropriate according to a direction according to which each constituent element is described. Therefore, appropriate replacements based on situations are allowed, and the positional relationships are not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate, a drain electrode, and a source electrode. The transistor has a channel region between the drain electrode (drain electrode terminal, drain region, or drain) and the source electrode (source electrode terminal, source region, or source), and a current may flow through the drain electrode, the channel region, and the source electrode. It is to be noted that in the specification, the channel region refers to a region through which a current mainly flows.

In the specification, a first pole may be a drain electrode, and a second pole may be a source electrode; or, the first pole may be a source electrode, and the second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of constituent elements through an element with a certain electrical action. An “element with a certain electrical action” is not particularly limited as long as electrical signals may be sent and received between the connected constituent elements. Examples of the “element with a certain electrical action” not only include an electrode and a wiring, but also include a switching element such as a transistor, a resistor, an inductor, a capacitor, another element with various functions, or the like.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, or hexagon, and the like in this specification are not strictly defined, and they may be approximate triangle, rectangle, trapezoid, pentagon, or hexagon, and the like. There may be some small deformations caused by tolerance, and there may be chamfer, arc edge, deformation, and the like.

In the present disclosure, “about” refers to that a boundary is not defined so strictly and numerical values within a range of process and measurement errors are allowed.

A liquid crystal display device has multiple display modes, such as ADS (Advanced Super Dimension Switch) mode, TN (Twisted Nematic) mode, VA (Vertical Alignment) mode, and the like. In the ADS mode, the first electrode and the second electrode are both located on a side of the array substrate. In the TN mode and the VA mode, the first electrode and the second electrode are respectively arranged on two opposite sides of the liquid crystal layer, the first electrode is located on a side of the array substrate, and the second electrode is located on a side of an opposite substrate.

The working principle of the ADS mode is that liquid crystal molecules are in a plane parallel to a glass substrate. When there is no voltage, light passes through a lower polarizing plate and then forms linearly polarized light parallel to a short axis of liquid crystal molecules. Since a direction of the polarized light cannot be rotated, it is absorbed by an upper polarizing plate and cannot be emitted. After applying a voltage, a transverse electric field is formed on the left and right sides of the liquid crystal, and the liquid crystal molecules are arranged in a direction of the electric field. After passing through the lower polarizing plate and the liquid crystal layer, the light is in an elliptically polarized state and may be emitted through the upper polarizing plate.

The working principle of TN mode is that in a voltage-free state, the liquid crystal molecules are twisted and aligned at 90° under the action of an alignment film, and light passes through the lower polarizing plate and the liquid crystal molecules and then is emitted from the upper polarizing plate. When a voltage is applied, most of the liquid crystal molecules are arranged vertically except the liquid crystal near matching films on upper and lower sides, and the light passing through the lower polarizing plate passes through the liquid crystal layer without deflection. Since it is parallel to a polarizing axis of the upper polarizing plate, the light is absorbed and cannot be emitted.

The working principle of VA mode is that liquid crystal molecules are aligned perpendicular to the glass substrate. When there is no voltage, light passes through the lower polarizing plate and then forms linearly polarized light parallel to a short axis of the liquid crystal molecules. Since a direction of the polarized light cannot be rotated, it is absorbed by the upper polarizing plate and cannot be emitted. After a voltage is applied, the liquid crystal molecules deflect along a direction of an electric field, and the light is in an elliptically polarized state after passing through the lower polarizing plate and the liquid crystal layer, and may be emitted through the upper polarizing plate.

A structure of the array substrate is described below by taking the ADS display mode array substrate structure as an example.

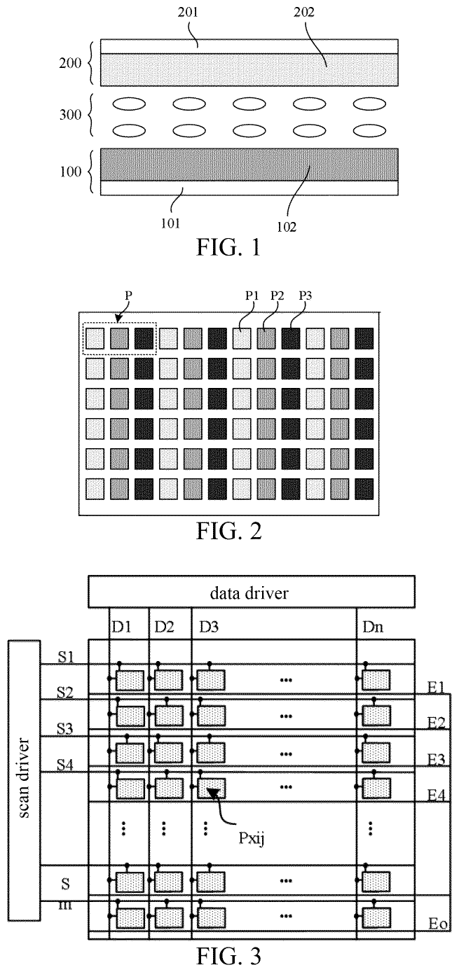

FIG. 1 is a schematic sectional view of a structure of a display device. As shown in FIG. 1, the display device may include an array substrate 100 and a color filter substrate 200 provided opposite to each other, and a liquid crystal layer 300 and a spacer layer provided between the array substrate 100 and the color filter substrate 200. The array substrate 100 may include a first structural layer 102 provided on a side of a first base substrate 101 facing the color filter substrate 200, and the color filter substrate 200 may include a second structural layer 202 provided on a side of a second base substrate 201 facing the array substrate 100. In an exemplary implementation, the first structural layer 102 may include a first wire, a second wire, a thin film transistor, a color filter layer, a first electrode, and a second electrode, and the second structural layer 202 may include a black matrix. The liquid crystal layer 300 may include multiple liquid crystal molecules having dielectric anisotropy. In response to an electric field applied between the array substrate 100 and the color filter substrate 200, the liquid crystal molecules may rotate in a predetermined direction between the array substrate 100 and the color filter substrate 200, thereby allowing or blocking transmission of light.

FIG. 2 is a schematic diagram of a planar structure of a display device. The display device may include a display area and a bezel area located at a periphery of the display area. As shown in FIG. 2, the display area of the display device may include multiple pixel units P arranged in a matrix, at least one of the multiple pixel units P includes a first sub-pixel P1 that emits first-color light, a second sub-pixel P2 that emits second-color light, and a third sub-pixel P3 that emits third-color light. Each of the three sub-pixels includes a thin film transistor, a first electrode, and a second electrode.

In an exemplary implementation, the first sub-pixel P1 may be a red sub-pixel that emits red (R) light, the second sub-pixel P2 may be a green sub-pixel that emits green (G) light, and the third sub-pixel P3 may be a blue sub-pixel that emits blue (B) light. A shape of sub-pixels in a pixel unit may be a rectangular shape, a diamond shape, a pentagonal shape, or a hexagonal shape, etc., and the sub-pixels in the pixel unit may be arranged side by side horizontally, side by side vertically, or arranged in a manner of a Chinese word “ [symbol] ”, which is not limited in the present disclosure.

In an exemplary implementation, the pixel unit may include four sub-pixels, which is not limited in the present disclosure.

In an exemplary implementation, the display device includes a display area having a rectangular shape. In some embodiments, the display area may also have a circular shape, an elliptical shape, or a polygonal shape such as a triangle and a pentagon.

In an exemplary implementation, the display device may be a tablet display device. In some embodiments, the display device may also employ other types of display devices, for example, flexible display devices, foldable display devices, rollable display devices, and the like.

FIG. 3 is a schematic diagram of a planar structure of an array substrate. As shown in FIG. 3, in an exemplary implementation, the array substrate may include multiple first wires (S1 to Sm) and multiple second wires (D1 to Dn), the multiple first wires may extend in a horizontal direction and be sequentially provided in a vertical direction, and the multiple second wires may extend in the vertical direction and be sequentially provided in the horizontal direction. The multiple first wires and the multiple second wires intersect with each other to define multiple regularly arranged sub-pixels Pxij, and i and j may be natural numbers. In an exemplary implementation, the sub-pixel Pxij may include a thin film transistor, a color filter layer, a second electrode, and a first electrode, and the thin film transistor is connected with the first wire, the second wire, and the first electrode, respectively.

In an exemplary implementation, multiple first wires are led out to the bezel area and connected with a scan driver, multiple second wires are led out to the bezel area and connected with a data driver, and at least a portion of the scan driver and the data driver may be formed on the array substrate.

In an exemplary implementation, an external control device (such as a timing controller) may provide a gray scale value and a control signal suitable for a specification of the data driver to the data driver, and the data driver may generate a data voltage to be provided to the data signal lines D1, D2, D3, . . . , and Dn using the received gray scale value and the control signal. For example, the data driver may sample the gray scale value using a clock signal and apply a data voltage corresponding to the gray scale value to the data signal lines D1 to Dn by taking a pixel row as a unit, where n may be a natural number. The external control device may provide a clock signal, a scan start signal, and the like suitable for a specification of the scan driver to the scan driver, and the scan driver may generate a scan signal to be provided to the scan signal lines S1, S2, S3, . . . , and Sm using the clock signal, the scan start signal, and the like. For example, the scan driver may provide sequentially a scan signal with an on-level pulse to the scan signal lines S1 to Sm, where m may be a nature number. For example, the scan driver may be constructed in a form of a shift register, and may generate a scan signal in a manner of sequentially transmitting a scan start signal provided in a form of an on-level pulse to a next-stage circuit under control of a clock signal.

An exemplary embodiment of the present disclosure provides an array substrate including: a base substrate; multiple first wires and multiple second wires provided on a side of the base substrate, the first wires extending in a first direction and the second wires extending in a second direction, the first wires and the second wires intersecting with each other to define multiple sub-pixels arranged in an array, each of the sub-pixels including at least one transistor, and the first direction and the second direction intersecting with each other; and a color filter layer, provided on a side of the transistor; the color filter layer including a color filter pattern corresponding to a sub-pixel, and an orthographic projection of the color filter pattern on the base substrate covering an orthographic projection of the transistor on the base substrate.

In an exemplary implementation, in the first direction, a portion of an orthographic projection of the color filter pattern corresponding to one sub-pixel of adjacent sub-pixels on the base substrate falls into an orthographic projection of the other sub-pixel of the adjacent sub-pixels on the base substrate.

In an exemplary implementation, an orthographic projection of a second wire between the adjacent sub-pixels on the base substrate overlaps with orthographic projections of respective color filter patterns of adjacent two sub-pixels on the base substrate.

In an exemplary implementation, an orthographic projection of a center line of the second wire on the base substrate overlaps with an orthographic projection of an overlapping boundary of the respective color filter patterns of the adjacent two sub-pixels on the base substrate.

In an exemplary implementation, a ratio of a distance in the first direction between a center line of the second wire that is perpendicular to the base substrate and an overlapping boundary of the respective color filter patterns of the adjacent two sub-pixels to a length of the second wire in the first direction is greater than 0 and less than or equal to 0.33.

The display substrate in the present disclosure is illustrated with examples below through some exemplary embodiments.

Hereinafter, the display device of this embodiment, which is a Liquid Crystal Display (LCD) device, is taken as an example. The display device of this embodiment may adopt a curved screen design, that is, edge areas or other areas of the array substrate and the color filter substrate in the display device form curved surfaces, but the display panel of this embodiment is not limited thereto.

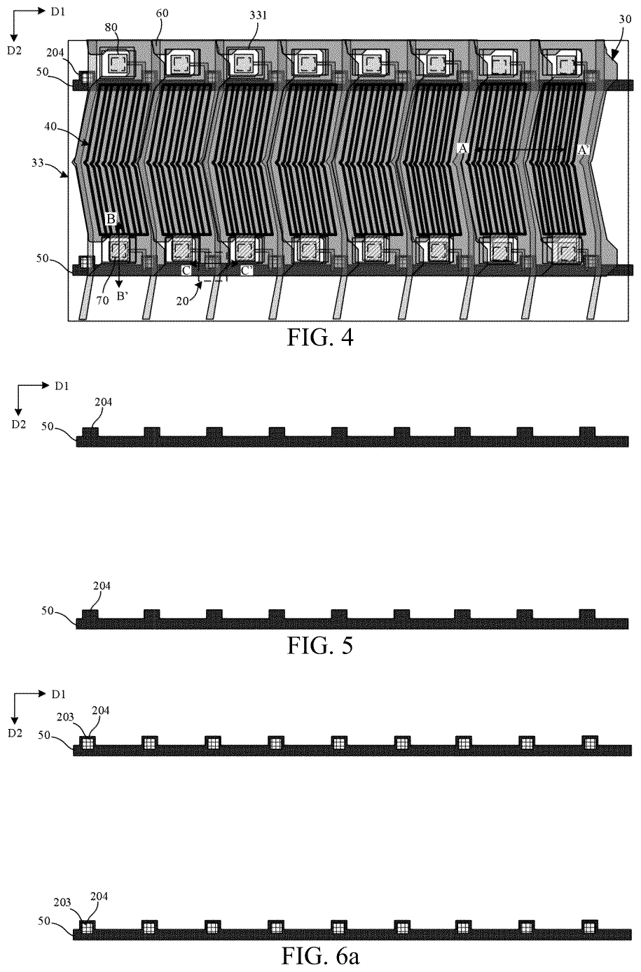

FIG. 4 is a schematic diagram of a planar structure of a display device according to an exemplary embodiment of the present disclosure. In an exemplary implementation, in a plane parallel to the display device, the display device of an embodiment of the present disclosure includes an array substrate and a color filter substrate that are provided oppositely, and a liquid crystal layer and a spacer layer provided between the array substrate and the color filter substrate. As shown in FIG. 4, in a direction parallel to the array substrate, the array substrate includes multiple first wires 50 and multiple second wires 60 provided on a first base substrate. The first wires 50 extend in a first direction D1 and are arranged at intervals in a second direction D2, and the first wires 50 are connected with a gate of a transistor 20. The second wires 60 extend in the second direction and the second wires 60 are connected with an electrode of the transistor 20. The first wires 50 and the second wires 60 intersect with each other to define multiple sub-pixels arranged in an array, and each of the sub-pixels includes at least one transistor 20. The first direction D1 and the second direction D2 are parallel to the array substrate, and the first direction D1 and the second direction D2 intersect with each other, by way of example, the first direction D1 and the second direction D2 are perpendicular to each other.

In an exemplary implementation, a first wire 50 may be integrally connected with the gate of the transistor 20, and the first wire 50 and the gate of the transistor 20 include a same conductive material. The gate of the transistor 20 may be a portion of the first wire 50 protruding in an opposite direction of the second direction D2.

In an exemplary implementation, a second wire 60 may be periodically bent, thereby improving the transmittance of the display device. For example, in one sub-pixel, the second wire 60 may be bent in a V-like shape, as shown in FIG. 4, thereby maximizing the transmittance of the display device.

In an exemplary implementation, the second wire 60 may be integrally connected with a second pole 220 of the transistor 20, and the second wire 60 and the second pole 220 of the transistor 20 include a same conductive material. The second pole 220 of the transistor 20 may be a portion of the second wire 60.

In an exemplary implementation, the first base substrate may be an insulation substrate and may be transparent. For example, the first base substrate 101 may be a glass substrate, a quartz substrate, a transparent resin substrate, or the like. The first base substrate 101 may include a polymer or a plastic material with a high heat resistance. In some implementations, the first base substrate 101 may be flexible. That is, the first base substrate 101 may be a substrate that can be deformed by rolling, folding, bending, or the like.

In an exemplary implementation, the array substrate further includes a color filter layer 30, and the color filter 30 is located on a side of the transistor 20. For example, the color filter layer 30 may be located on a side of the transistor 20 close to the first base substrate; or, the color filter layer 30 may be located on a side of the transistor 20 away from the first base substrate. The color filter layer 30 includes a color filter pattern corresponding to the sub-pixel, and an orthographic projection of the color filter pattern on the base substrate covers an orthographic projection of the transistor on the base substrate.

In an exemplary implementation, the array substrate further includes a second electrode 33 provided on a side of the transistor 20 away from the first base substrate and a first electrode 40 provided on a side of the second electrode 33 away from the first base substrate. An orthographic projection of the first electrode 40 on the base substrate overlaps with an orthographic projection of the second electrode 33 on the base substrate, and the first electrode 40 may be connected with a first pole of the transistor 20.

In an exemplary implementation, the display device of an embodiment of the present disclosure further includes a contact hole 70 and a connection electrode 80. The connection electrode 80 is connected with the first pole of the transistor 20. The contact hole 70 extends in a direction perpendicular to the first base substrate, and an orthographic projection of the contact hole 70 on the first base substrate overlaps with an orthographic projection of the connection electrode 80 on the first base substrate. By way of example, the orthographic projection of the contact hole 70 on the first base substrate is located in the orthographic projection of the connection electrode 80 on the first base substrate. The contact hole 70 exposes at least a portion of a surface of the connection electrode 80. At least a portion of the first electrode 40 extends to a region where the contact hole 70 is located, and an orthographic projection of at least a portion of the first electrode 40 on the first base substrate overlaps with the orthographic projection of the contact hole 70 on the first base substrate. The first electrode 40 is connected with the exposed connection electrode 80 through the contact hole 70, so that the first electrode 40 may be connected with the first pole of the transistor 20 through the connection electrode 80, and the first electrode 40 may receive a voltage from the first pole of the transistor 20.

In an exemplary implementation, a shape of the orthographic projection of the contact hole 70 on the first base substrate may include a rectangle. In some embodiments, the shape of the orthographic projection of the contact hole on the first base substrate may include a rounded rectangle, a circle, an oval, a triangle, a rhombus, a trapezoid, a pentagon, a hexagon, and the like.

Exemplary description is made below through a process of manufacturing an array substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, and the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B being arranged on a same layer” in the present disclosure means that A and B are formed simultaneously through a same patterning process, and the “thickness” of a film layer is dimension of the film layer in a direction perpendicular to the array substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In an exemplary implementation, the process of manufacturing the array substrate according to this embodiment may include the following acts.
(11) Forming a first conductive layer. In an exemplary implementation, forming the first conductive layer may include depositing a first conductive thin film on a first base substrate, and patterning the first conductive thin film by a patterning process to form the first conductive layer. The first conductive layer includes multiple first wires 50 and multiple gates 204, as shown in FIG. 5.

In an exemplary implementation, the first wires 50 extend in a first direction D1 and are arranged at intervals in a second direction D2.

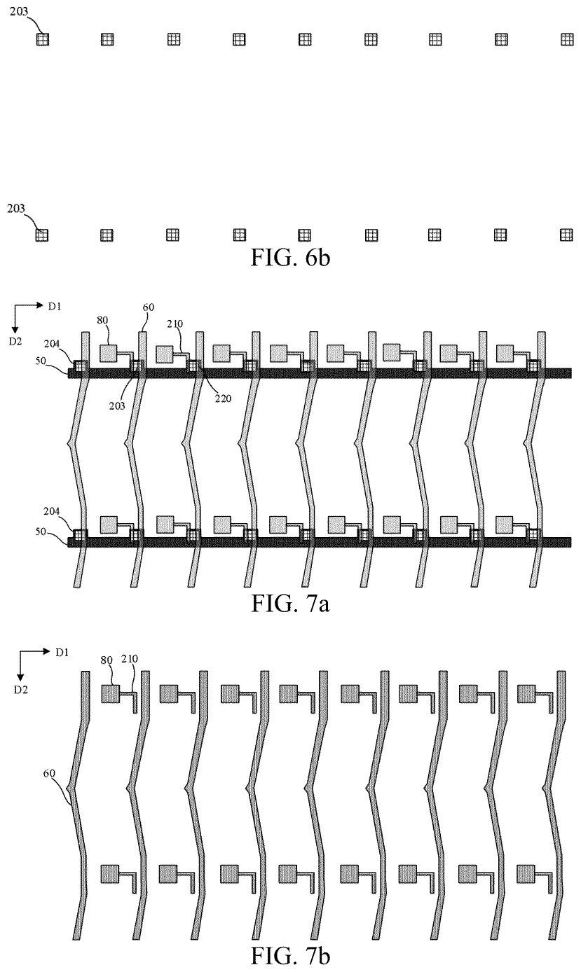

In an exemplary implementation, a shape of a gate 204 is a block shape. The multiple gates 204 are provided on a side edge of the first wire 50 in an opposite direction of the second direction D2 and the multiple gates 204 are arranged at intervals in the first direction D1. The gate 204 is integrally connected with the first wire 50, the gate 204 and the first wire 50 include a same conductive material, and the gate 204 may be a portion of the first wire 50 protruding in the opposite direction of the second direction D2.
(12) Forming an active layer. In an exemplary implementation, forming the active layer may include depositing a semiconductor thin film on a side of the first conductive layer away from the first base substrate on a base substrate on which the aforementioned patterns are formed, and patterning the semiconductor thin film by a patterning process to form multiple active layers 203, as shown in FIGS. 6a and 6b.

In an exemplary implementation, a shape of the active layer 203 is a block shape, for example, a rectangular block shape. An orthographic projection of the active layer 203 on the first base substrate overlaps with an orthographic projection of the gate 204 on the first base substrate, by way of example, the orthographic projection of the active layer 203 on the first base substrate is located in the orthographic projection of the gate 204 on the first base substrate.
(13) Forming a second conductive layer. In an exemplary implementation, forming the second conductive layer may include depositing a second conductive thin film on a side of the active layer away from the first base substrate on the base substrate on which the aforementioned patterns are formed, and patterning the second conductive thin film by a patterning process, to form the second conductive layer. The second conductive layer includes multiple second wires 60, multiple connection electrodes 80, and multiple first poles 210, as shown in FIGS. 7a and 7b.

In an exemplary implementation, the second wires 60 extends in the second direction D2, multiple second wires 60 are arranged at intervals in the first direction D1, and the second wires 60 and the first wires 50 intersect with each other to define multiple sub-pixels arranged in an array. The second wires 60 may be periodically bent, thereby improving the transmittance of the display device.

In an exemplary implementation, an orthographic projection of at least a portion of a second wire 60 on the first base substrate overlaps with an orthographic projection of the active layer 203 on the first base substrate, and a region where the second wire 60 overlaps with the active layer 203 forms a second pole 220.

In an exemplary implementation, a shape of the connection electrode 80 is a block shape, for example, a rectangular block shape. The connection electrodes 80 are located on a side of the second wire 60 in an opposite direction of the first direction D1, and an orthographic projection of the connection electrode 80 on the first base substrate does not overlap with both an orthographic projection of the first wire 50 on the first base substrate and an orthographic projection of the second wire 60 on the first base substrate.

In some embodiments, a shape of an orthographic projection of the connection electrode on the first base substrate may include a rounded rectangle, a circle, an oval, a triangle, a rhombus, a trapezoid, a pentagon, a hexagon, and the like.

In an exemplary implementation, a shape of a first pole 210 is an L-shape. A first end of the first pole 210 is connected with the connection electrode 80, and an orthographic projection of a second end of the first pole 210 on the first base substrate overlaps with an orthographic projection of the active layer 203 on the first base substrate.

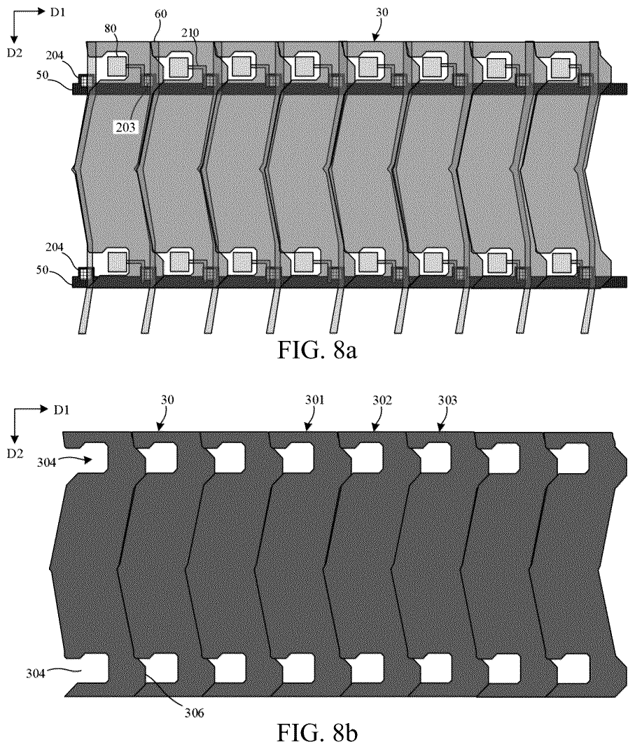

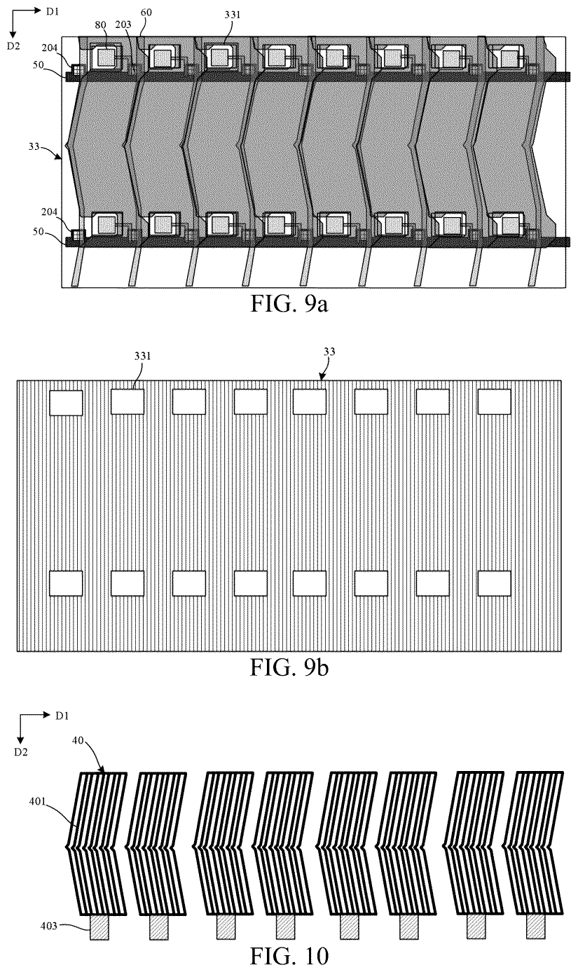

In an exemplary implementation, the first pole 210, the second pole 220, the active layer 203, and the gate 204 form a transistor of a sub-pixel.
(14) Forming a color filter layer. In an exemplary implementation, forming the color filter layer may include depositing a color filter thin film on a side of the second conductive layer away from the first base substrate on a base substrate on which the aforementioned patterns are formed, and patterning the color filter thin film by a patterning process to form the color filter layer 30. The color filter layer 30 includes a color filter pattern corresponding to a sub-pixel, and an orthographic projection of the color filter pattern on the base substrate covers an orthographic projection of the transistor on the base substrate, as shown in FIGS. 8a and 8b.

In an exemplary implementation, the color filter layer 30 includes a first color filter pattern 301 that transmits a first color, a second color filter pattern 302 that transmits a second color, and a third color filter pattern 303 that transmits a third color. The first color filter pattern 301, the second color filter pattern 302, and the third color filter pattern 303 are arranged sequentially in the first direction D1, the first color filter pattern 301 is adjacent to the second color filter pattern 302, and at least a portion of an edge of the first color filter pattern 301 is connected with at least a portion of an edge of the second color filter pattern 302. The second color filter pattern 302 is adjacent to the third color filter pattern 303, and at least a portion of an edge of the second color filter pattern 302 is connected with at least a portion of an edge of the third color filter pattern 303.

In an exemplary implementation, the color filter pattern includes a hollowed-out region 304, and the orthographic projection of the connection electrode 80 on the first base substrate overlaps with an orthographic projection of the hollowed-out region 304 on the first base substrate. The hollowed-out region 304 of the color filter pattern is connected with an edge of adjacent color filter pattern in the opposite direction of the first direction D1.

In an exemplary implementation, the color filter pattern corresponding to one sub-pixel of the adjacent sub-pixels is provided with a bump 306 at one side in the first direction D1. An orthographic projection of the bump 306 on the base substrate is located in an orthographic projection of the other sub-pixel of the adjacent sub-pixels on the base substrate, and the bump 306 extends into the hollowed-out region 304 of the color filter pattern corresponding to the adjacent sub-pixel.

In an exemplary implementation, a shape of the bump 306 includes a trapezoid.
(15) Forming a third conductive layer. In an exemplary implementation, forming the third conductive layer may include depositing a third conductive thin film on a side of the second conductive layer away from the first base substrate on the base substrate on which the aforementioned patterns are formed, and patterning the third conductive thin film by a patterning process to form a third conductive layer. The third conductive layer includes a second electrode 33, as shown in FIGS. 9a and 9b.

In an exemplary implementation, the second electrode 33 may cover multiple sub-pixels. The second electrode 33 is provided with an avoidance hole 331, an orthographic projection of the avoidance hole 331 on the first base substrate includes an orthographic projection of the connection electrode 80 on the first base substrate 101, and the avoidance hole 331 exposes the connection electrode 80.
(16) Forming a fourth conductive layer. In an exemplary implementation, forming the fourth conductive layer may include depositing a fourth conductive thin film on a side of the third conductive layer away from the first base substrate on the base substrate on which the aforementioned patterns are formed, and patterning the fourth conductive thin film by a patterning process to form a fourth conductive layer. The fourth conductive layer includes a first electrode 40, as shown in FIGS. 4a and 10.

In an exemplary implementation, the first electrode 40 may be a slit electrode, and the first electrode 40 may include multiple branch electrodes 401 and slits 402 formed between the branch electrodes 401, orthographic projections of the multiple branch electrodes 401 on the first base substrate overlapping with an orthographic projection of the second electrode 33 on the first base substrate. A branch electrode 401 may be substantially parallel to the second wire 60 and may extend according to a profile of the second wire 60. For example, the second wire 60 is bent in a V-shape, and each branch electrode 401 may be formed with an edge bent in a V-shape. An extension direction of the slit 402 of the first electrode 40 is not specifically limited, and the extension direction of the slit 402 may be in the second direction D2 or may form a certain angle with the second direction D2.

In an exemplary implementation, the first electrode 40 may employ a transparent conductive material, for example, ITO, IZO, ITZO, AZO, or the like.

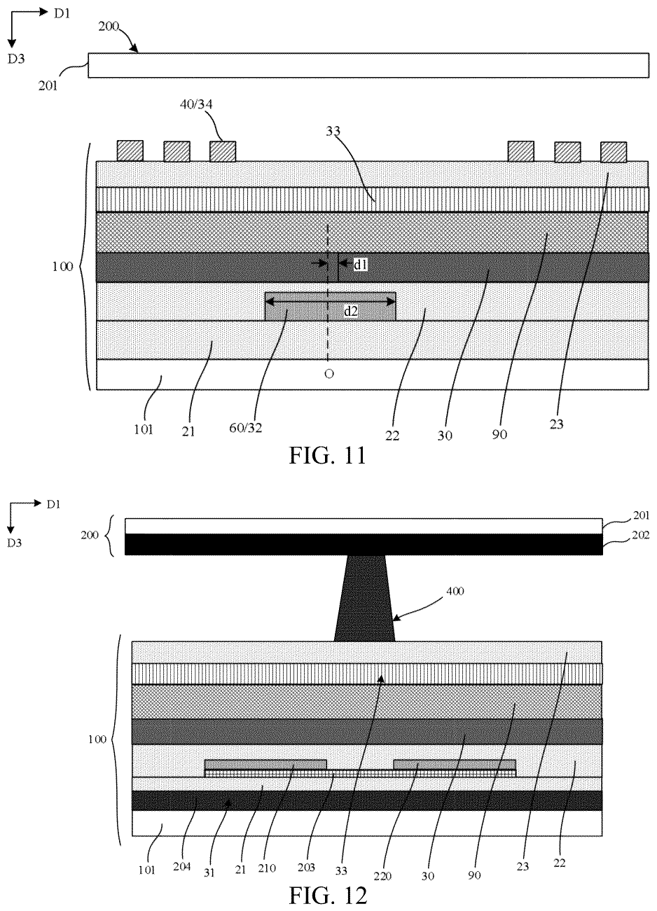

In an exemplary implementation, an extension part 403 is provided on a side of the first electrode 40 in the second direction D2, a first end of the extension part 403 is connected with the first electrode 40, and a second end of the extension part 403 extends in the second direction D2. An orthographic projection of at least a portion of the extension part 403 on the first base substrate overlaps with an orthographic projection of the connection electrode 80 on the first base substrate, and the extension part 403 may be connected with the connection electrode 80. FIG. 11 is a schematic sectional view of a structure of a display device according to an exemplary embodiment of the present disclosure. FIG. 11 may be a sectional view taken along A-A′ direction in FIG. 4. In an exemplary implementation, in a plane perpendicular to the display device, as shown in FIG. 11, the display device of an embodiment of the present disclosure may include an array substrate 100 and a color filter substrate 200 that are provided oppositely, and a liquid crystal layer and a spacer layer (not shown in figures) provided between the array substrate 100 and the color filter substrate 200. The color filter substrate 200 may include a second base substrate 201. The array substrate 100 may include a first base substrate 101, a first insulation layer 21 provided on the first base substrate 101, a second conductive layer 32 provided on a side of the first insulation layer 21 away from the first base substrate 101, a second insulation layer 22 provided on a side of the second conductive layer 32 away from the first base substrate 101, a color filter layer 30 provided on a side of the second insulation layer 22 away from the first base substrate 101, an organic dielectric layer 90 provided on a side of the color filter layer 30 away from the first base substrate 101, a third conductive layer provided on a side of the organic dielectric layer 90 away from the first base substrate 101, a third insulation layer 23 provided on a side of the third conductive layer away from the first base substrate 101, and a fourth conductive layer 34 provided on a side of the third insulation layer 23 away from the first base substrate 101.

In an exemplary implementation, the second base substrate 201 may be an insulation substrate and may be transparent. For example, the second base substrate 201 may be a glass substrate, a quartz substrate, a transparent resin substrate, or the like. The second base substrate 201 may include a polymer or plastic material with a high heat resistance. In some implementations, the second base substrate 201 may be flexible. That is, the first base substrate 101 may be a substrate that can be deformed by rolling, folding, bending, or the like.

In an exemplary implementation, the first insulation layer 21, the second insulation layer 22, and the third insulation layer 23 may employ an inorganic material, such as silicon nitride or silicon oxide.

In an exemplary implementation, the second conductive layer 32 may include a second wire 60. An orthographic projection of the second wire 60 on the first base substrate 101 does not overlap with an orthographic projection of the first electrode 40 on the first base substrate 101.

In an exemplary implementation, the color filter layer 30 may include multiple color filter patterns that may transmit light of different colors.

In an exemplary implementation, an orthographic projection of the second wire 60 between the adjacent sub-pixels on the first base substrate overlaps with orthographic projections of the respective color filter patterns of the adjacent two sub-pixels on the first base substrate.

In an exemplary implementation, a distance in the first direction D1 between a center line O of the second wire 60 that is perpendicular to the first base substrate and an overlapping boundary of the respective color filter patterns of the adjacent two sub-pixels is d1, a length of the second wire 60 in the first direction D1 is d2, and a ratio of d1 to d2 is greater than 0 and less than or equal to 0.33.

In some embodiments, an orthographic projection of the center line O of the second wire 60 that is perpendicular to the first base substrate on the base substrate overlaps with an orthographic projection of the overlapping boundary of the respective color filter patterns of the adjacent two sub-pixels on the base substrate.

In an exemplary implementation, an orthographic projection of the organic dielectric layer 90 on the first base substrate 101 overlaps with an orthographic projection of the color filter layer 30 on the first base substrate 101, and the organic dielectric layer 90 covers multiple color filter patterns that transmit light of different colors. A surface of the organic dielectric layer 90 close to the first base substrate 101 is in contact with the color filter layer 30, and a surface of the organic dielectric layer 90 away from the first base substrate 101 is planarized. Thicknesses of the color filter patterns that transmit light of different colors are different, and the organic dielectric layer 90 may planarize a surface of the color filter layer 30, make up for the segmentation difference between the adjacent color filter patterns, and ensure the planarization of the subsequent film layer during manufacturing.

In an exemplary implementation, the third conductive layer includes a second electrode 33, and an orthographic projection of the second electrode 33 on the first base substrate 101 overlaps with an orthographic projection of the color filter layer 30 on the first base substrate 101 In an exemplary implementation, the fourth conductive layer 34 includes a first electrode 40, the first electrode 40 may be in direct contact with the third insulation layer 23, and an orthographic projection of the first electrode 40 on the first base substrate 101 overlaps with an orthographic projection of the color filter layer 30 on the first base substrate 101. The orthographic projection of the first electrode 40 on the first base substrate 101 overlaps with an orthographic projection of the second electrode on the first base substrate 101.

FIG. 12 is a schematic sectional view of a structure of a display device according to an exemplary embodiment of the present disclosure. FIG. 12 is a sectional view taken along C-C′ direction in FIG. 4. In an exemplary implementation, in a plane perpendicular to the display device, as shown in FIG. 12, the display device of an embodiment of the present disclosure may include an array substrate 100 and a color filter substrate 200 that are provided oppositely, and a liquid crystal layer and a spacer layer 400 provided between the array substrate 100 and the color filter substrate 200. The color filter substrate 200 may include a second base substrate 201 and a black matrix 202 provided on a side of the second base substrate 201 close to the array substrate 100. The array substrate 100 may include a first base substrate 101, a first conductive layer 31 provided on the first base substrate 101, a first insulation layer 21 provided on a side of the first conductive layer 31 away from the first base substrate 101, a semiconductor layer provided on a side of the first insulation layer 21 away from the first base substrate 101, a second conductive layer provided on a side of the semiconductor layer away from the first base substrate 101, a second insulation layer 22 provided on a side of the second conductive layer away from the first base substrate 101, a color filter layer 30 provided on a side of the second insulation layer 22 away from the first base substrate 101, an organic dielectric layer 90 provided on a side of the color filter layer 30 away from the first base substrate 101, a third conductive layer provided on a side of the organic dielectric layer 90 away from the first base substrate 101, and a third insulation layer 23 provided on a side of the third conductive layer away from the first base substrate 101.

In an exemplary implementation, the first conductive layer 31 may include a first wire and a gate, the first wire may be integrally connected with the gate, and the first wire and the gate include a same conductive material. The first wire and the gate may be formed of an aluminum (Al)-based metal such as Al or Al alloy, a silver (Ag)-based metal such as Ag or Ag alloy, a copper (Cu)-based metal such as Cu or Cu alloy, a molybdenum (Mo)-based metal such as Mo or Mo alloy, chromium (Cr), tantalum (Ta), titanium (Ti), and the like. At least one of the first wire and the gate may have a mono-layer structure or may include a multi-layer structure of two conductive films with different physical properties. For example, one of the two conductive films may be formed of a low resistance metal (such as, Al-based metal, Ag-based metal, Cu-based metal, or the like) to reduce signal delay or voltage drop in the first wire, and the other conductive film may be formed of a material (such as, Mo-based metal, Cr, Ti, Ta, or the like) with excellent contact properties similar to indium tin oxide (ITO) and indium zinc oxide (IZO). For example, the multi-layer structure of the first wire and gate includes a combination of a Cr lower film and an Al upper film or a combination of an Al lower film and an Mo upper film, but the present disclosure is not limited thereto.

In some embodiments, the first wire and the gate may be located in different film layers, and may be connected by a via, and the first wire and the gate may include different conductive materials.

In an exemplary implementation, the first insulation layer 21 may serve as a gate insulation layer of the transistor for separating the gate from the active layer. The first insulation layer 21 may be a single film layer structure or a multi-film layer structure.

In an exemplary implementation, the semiconductor layer includes an active layer 203, and an orthographic projection of the active layer 203 on the first base substrate 101 overlaps with an orthographic projection of the gate on the first base substrate 101. By way of example, the orthographic projection of the active layer 203 on the first base substrate 101 is located in the orthographic projection of the gate on the first base substrate 101.

In an exemplary implementation, the active layer 203 may include a metal oxide, for example, Indium Gallium Zinc Oxide (IGZO).

In an exemplary implementation, the second conductive layer includes a first pole 210 and a second pole 220, and the first pole 210 and the second pole 220 are connected by the active layer 203. The first pole 210 may serve as a drain electrode of the transistor and be connected with the first electrode through a contact hole. The second pole 220 may serve as a source electrode of the transistor and be integrally connected with the second wire. The gate, the active layer 203, the first pole 210, and the second pole 220 form the transistor of the array substrate.

In an exemplary implementation, the second conductive layer may be formed of Al, Cu, Ag, Mo, Cr, Ti, Ta, or an alloy thereof, and may have a mono-layer structure or a multi-layer structure. The multi-layer structure includes a lower film formed of a refractory metal and a low resistance upper film formed on the lower film, but the present disclosure is not limited thereto.

According to a calculation formula for capacitance c=ε s/d, where c is a capacitance value, ε is a dielectric constant of a medium between capacitance plates, s is a relative area of the capacitance plates, and d is a vertical distance between the capacitance plates. A display device of an embodiment of the present disclosure increases the thickness of the film layer between the second conductive layer and the third conductive layer by providing a color filter layer between the second conductive layer and the third conductive layer, and reduces the capacitance value between the first electrode and the second electrode in the second conductive layer, thereby reducing the load of the display device and further reducing the power consumption of the display device.

A display device of an embodiment of the present disclosure increases the thickness of the film layer between the first conductive layer and the third conductive layer by providing a color filter layer between the first conductive layer and the third conductive layer, and reduces the capacitance value between the gate and the second electrode in the first conductive layer, thereby reducing the load of the display device and further reducing the power consumption of the display device.

A display device of an embodiment of the present disclosure improves the performance of the display device, increases the aperture ratio, improves the transmittance, and improves problems, for example, poor display by providing the color filter layer in the array substrate.

In an exemplary implementation, the spacer layer 400 is provided on the third insulation layer 23 and is in direct contact with the third insulation layer 23. The spacer layer 400 is used for supporting the array substrate 100 and the color filter substrate 200, separating the array substrate 100 and the color filter substrate 200, and maintaining a distance between the array substrate 100 and the color filter substrate 200.

A display device of the present disclosure provides the spacer layer 400 on the array substrate 100, so that during the alignment process of the array substrate 100 and the color filter substrate 200, only the spacer layer 400 of the array substrate 100 and the black matrix 202 of the color filter substrate 200 need to be aligned, thereby reducing the difficulty of alignment. In addition, a surface of the black matrix is flat, and after the spacer layer 400 is aligned with the black matrix 202, a height of the spacer layer 400 may be ensured to be consistent, thereby avoiding the display differences caused by the height inconsistency of the spacer layer 400 and ensuring the display effects.

In an exemplary implementation, a section of the spacer layer 400 perpendicular to the first base substrate includes at least one of a rectangle, a regular trapezoid, and an inverted trapezoid.

In an exemplary implementation, the black matrix 202 of the color filter substrate 200 may extend in the first direction D1, and an orthographic projection of the black matrix 202 of the color filter substrate 200 on the first base substrate overlaps with an orthographic projection of at least a portion of the first wire of the array substrate 100 on the first base substrate, and does not overlap with an orthographic projection of at least a portion of the second wire of the array substrate 100 on the first base substrate. By way of example, an extension direction of the black matrix 202 is the same as an extension direction of the first wire, and an orthographic projection of the black matrix 202 on the first base substrate overlaps with an orthographic projection of the first wire on the first base substrate, and does not overlap with an orthographic projection of the second wire on the first base substrate. A display device of the present disclosure may adopt the second wire as a black matrix to block light, thereby simplifying the production process and reducing the production cost.

FIG. 13 is a schematic sectional view of a structure of a display device according to an exemplary embodiment of the present disclosure. FIG. 13 may be a sectional view taken along B-B′ direction in FIG. 4. In an exemplary implementation, in a plane perpendicular to the display device, as shown in FIG. 13, the display device of an embodiment of the present disclosure may include an array substrate 100 and a color filter substrate 200 that are provided oppositely, and a liquid crystal layer and a spacer layer provided between the array substrate 100 and the color filter substrate 200. The color filter substrate 200 may include a second base substrate 201 and a black matrix 202 provided on a side of the second base substrate 201 close to the array substrate 100. The array substrate 100 may include a first base substrate 101, a first conductive layer provided on a first base substrate 101, a first insulation layer 21 provided on a side of the first conductive layer away from the first base substrate 101, a second conductive layer provided on a side of the first insulation layer 21 away from the first base substrate 101, a second insulation layer 22 provided on a side of the second conductive layer away from the first base substrate 101, a color filter layer 30 provided on a side of the second insulation layer 22 away from the first base substrate 101, an organic dielectric layer 90 provided on a side of the color filter layer 30 away from the first base substrate 101, a third conductive layer provided on a side of the organic dielectric layer 90 away from the first base substrate 101, a third insulation layer 23 provided on a side of the third conductive layer away from the first base substrate 101, and a fourth conductive layer provided on a side of the third insulation layer 23 away from the first base substrate 101.

In an exemplary implementation, the first conductive layer includes a first wire 50 extending in the first direction, and the first wire 50 is connected with the gate of the transistor. The second conductive layer includes a connection electrode 80 and the connection electrode 80 is connected with the first pole of the transistor. The third conductive layer includes a second electrode 33. The fourth conductive layer includes a first electrode 40.

In an exemplary implementation, the connection electrode 80 and the first pole of the transistor are located in a same film layer and integrally connected, and the connection electrode 80 and the first pole of the transistor may include a same conductive material. In some embodiments, the connection electrode may be located in a different film layer from the first pole of the transistor, and the connection electrode and the first pole of the transistor are connected through a via.

In an exemplary implementation, a display device of an embodiment of the present disclosure may further include a contact hole 70. The contact hole 70 extends from a surface of the third insulation layer 23 away from the first base substrate 101, sequentially through the third insulation layer 23, the organic dielectric layer 90, and a portion of the second insulation layer 22, to a surface of the connection electrode 80 away from the first base substrate 101, exposing at least a portion of a surface of the connection electrode 80. An orthographic projection of the contact hole 70 on the first base substrate 101 does not overlap with an orthographic projection of the second electrode on the first base substrate 101. The first electrode 40 covers at least a portion of the inner wall of the contact hole 70, for example, the first electrode 40 covers a side wall and a bottom wall of the contact hole 70, and the first electrode 40 is in direct contact with the exposed connection electrode 80 through the contact hole 70.

In an exemplary implementation, an orthographic projection of a side of the contact hole 70 away from the first base substrate 101 on the first base substrate 101 is located in an orthographic projection of a side of the contact hole 70 close to the first base substrate 101 on the first base substrate 101. A section of the contact hole 70 perpendicular to the first base substrate 101 has an inverted trapezoid with a bigger upper part and a smaller lower part.

In an exemplary implementation, the contact hole 70 at least includes a first via 701 provided in the organic dielectric layer 90 and a second via 702 provided in the third insulation layer 23, the first via 701 penetrates the organic dielectric layer 90 in a direction perpendicular to the first base substrate 101, and the second via 702 penetrates the third insulation layer 23 in a direction perpendicular to the first base substrate 101. The first via 701 communicates with the second via 702 and the first via 701 and the second via 702 may be formed simultaneously by a single etching process. An orthographic projection of the first via 701 on the first base substrate 101 is located in an orthographic projection of the second via 702 on the first base substrate 101, and the orthographic projection of the second via 702 on the first base substrate 101 is located in an orthographic projection of the connection electrode 80 on the first base substrate 101.

In an exemplary implementation, the color filter layer 30 includes a color filter pattern, the color filter pattern includes a hollowed-out region 304, the color resistance material in the hollowed-out region 304 is etched off, and a portion of the material of the organic dielectric layer 90 is filled into the hollowed-out region 304. An orthographic projection of the contact hole 70 on the first base substrate 101 is located in an orthographic projection of the hollowed-out region 304 on the first base substrate 101, so that an orthographic projection of the contact hole 70 on the first base substrate 101 does not overlap with an orthographic projection of the color filter layer 30 on the first base substrate 101.

In a display device of an embodiment of the present disclosure, the orthographic projection of the contact hole 70 on the first base substrate 101 is located in the orthographic projection of the hollowed-out region 304 on the first base substrate 101, the color filter layer 30 is prevented from being penetrated during the process of forming the contact hole, and the color filter layer 30 is prevented from being broken during the process of forming the contact hole. In addition, the quantity of film layers being penetrated during the process of forming the contact hole is reduced, the risk of a large deviation between the aperture size of the contact hole 70 and the designed size is reduced, and the problem such as residual color filter layer material in the contact hole 70 is solved.

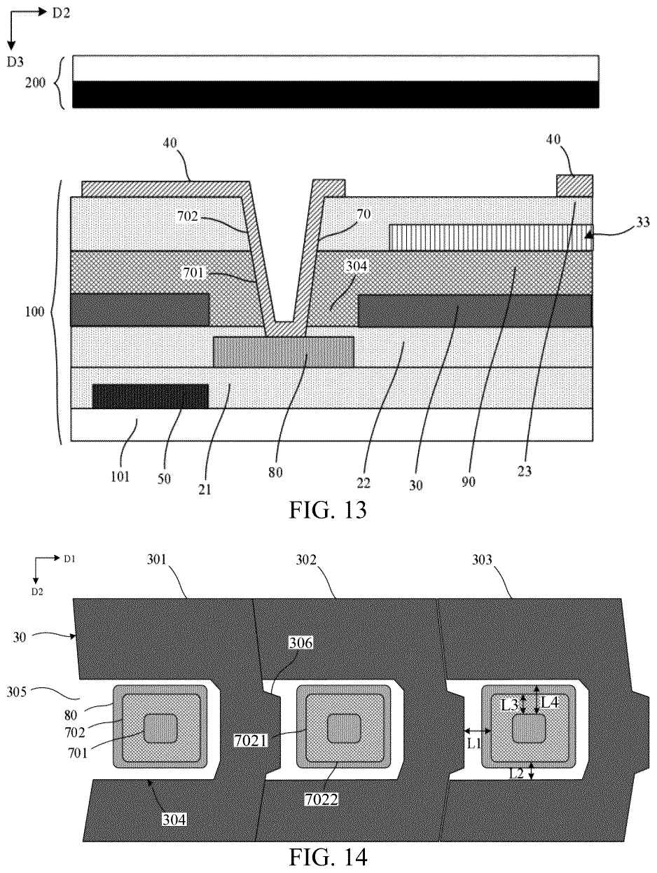

FIG. 14 is a schematic partial planar view of a display device according to an exemplary embodiment of the present disclosure. FIG. 14 is an enlarged view at position a in FIG. 4. In an exemplary implementation, as shown in FIG. 14, the color filter pattern includes a hollowed-out region 304. The connection electrode 80, and the first via 701 and the second via 702 of the contact hole are all located in the hollowed-out region 304, and orthographic projections of the connection electrode 80, and the first via 701 and the second via 702 of the contact hole on the first base substrate all overlap with an orthographic projection of the hollowed-out region 304 on the first base substrate. An opening 305 is provided on a side of the hollowed-out region 304 in an opposite direction of the first direction D1 and the other sides of the hollowed-out region 304 are provided around the circumferential side of the contact hole. The other sides of the hollowed-out region 304 may include one side of the hollowed-out region 304 in the first direction D1 and two opposite sides of the hollowed-out region 304 in the second direction D2. The opening 305 of the hollowed-out region 304 of the color filter pattern is adjacent to an edge of the adjacent color filter pattern, by way of example, the opening 305 of the hollowed-out region 304 of the color filter pattern is connected with an edge of the adjacent color filter pattern. In some embodiments, openings are provided on two opposite sides of the hollowed-out region in the first direction, which will not be described herein in an embodiment of the present disclosure.

In an exemplary implementation, the color filter pattern is provided with a bump 306 at a side edge in the first direction D1. The bump 306 protrudes into the opening 305 of the hollowed-out region of the adjacent color filter pattern, such that at least a portion of the bump 306 is located in the hollowed-out region of the adjacent color filter pattern.

In an exemplary implementation, a shape of an orthographic projection of the second via 702 of the contact hole on the first base substrate is a rounded rectangle. The second via 702 has a first edge portion 7021 and a second edge portion 7022, the first edge portion 7021 is adjacent to a bump 306 of the adjacent color filter pattern, and the second edge portion 7022 is adjacent to other sides of the hollowed-out region 304. A minimum perpendicular distance between the first edge portion 7021 and an edge of the bump 306 of the adjacent color filter pattern is L1, a minimum perpendicular distance between the second edge portion 7022 and the other sides of the hollowed-out region is L2, and the L1 is greater than or equal to the L2.

In a display device of an embodiment of the present disclosure, the minimum perpendicular distance between the first edge portion 7021 and an edge of the bump 306 of the adjacent color filter pattern is greater than or equal to a minimum perpendicular distance between the second edge portion 7022 and the other sides of the hollowed-out region. As a result, a slope of the contact hole is gentle, and the slope of the contact hole is prevented from being steep, which would cause the color resistance material to remain in the contact hole and the failure of the electrical connection.

In an exemplary implementation, a ratio of the L1 to the L2 is less than or equal to 4 and greater than or equal to 1. For example, the ratio of the L1 to the L2 is less than or equal to 2 and greater than or equal to 1, so that the slope of the contact hole is gentle, the residue of the color resistance material is avoided, and the electrical connection is guaranteed.

In an exemplary implementation, the L1 is greater than or equal to 7 microns. By way of example, the L1 is greater than or equal to 10 microns and less than or equal to 15 microns, so that the slope of the contact hole is gentle, the residue of the color resistance material is avoided, and the electrical connection is guaranteed.

In an exemplary implementation, the L2 is greater than or equal to 5.5 microns. By way of example, the L2 is greater than or equal to 7 microns and less than or equal to 10 microns, so that the slope of the contact hole is gentle, the residue of color resistance material is avoided, and the electrical connection is guaranteed.

In an exemplary implementation, an orthographic projection of the second via 702 on the first base substrate is located in an orthographic projection of the connection electrode 80 on the first base substrate. A minimum perpendicular distance between an edge of an orthographic projection of the first via 701 on the first base substrate and an edge of the orthographic projection of the second via 702 on the first base substrate is L3, and a minimum perpendicular distance between an edge of the orthographic projection of the first via 701 on the first base substrate and an edge of the orthographic projection of the connection electrode 80 on the first base substrate is L4, and the L4 is greater than the L3, so that the regions exposed by the contact hole are all connection electrodes 80, thereby ensuring the electrical connection between the first electrode and the connection electrode.

In an exemplary implementation, a ratio of the L4 to the L3 is less than or equal to 4 and greater than or equal to 1.1. By way of example, the ratio of the L4 to the L3 is less than or equal to 2 and greater than or equal to 1.1, thereby ensuring the electrical connection between the first electrode and the connection electrode.

In an exemplary implementation, the L3 is greater than or equal to 3.5 microns. By way of example, the L3 is greater than or equal to 5 microns and less than or equal to 7.5 microns, so as to ensure the electrical connection between the first electrode and the connection electrode.

In an exemplary implementation, the L4 is greater than or equal to 4.5 microns. By way of example, the L3 is greater than or equal to 8 microns and less than or equal to 10 microns, so as to ensure the electrical connection between the first electrode and the connection electrode.

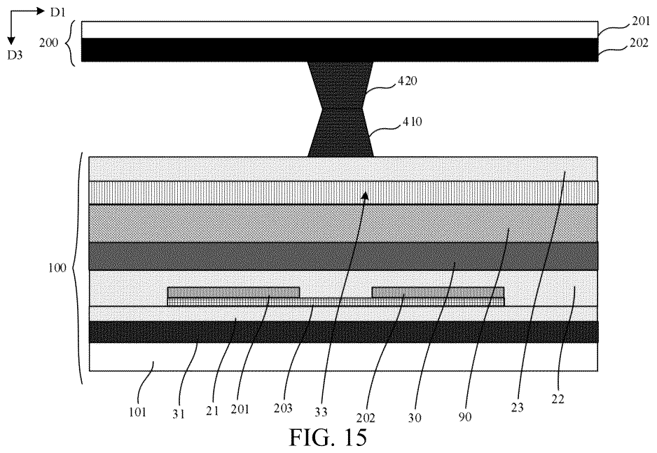

FIG. 15 is a schematic sectional view of a structure of a display device according to an exemplary embodiment of the present disclosure. In the exemplary implementation, in a plane perpendicular to the display device, the structure of the display device of this exemplary embodiment is substantially the same as the structure of the display device of the foregoing embodiment, except that as shown in FIG. 15, a first spacer layer 410 is provided on a side of the third insulation layer 23 of the array substrate 100 of the display device of this exemplary embodiment close to the color filter substrate 200. The color filter substrate 200 may include a second base substrate 201 and a black matrix 202 provided on a side of the second base substrate 201 close to the array substrate 100. A second spacer layer 420 is provided on a side of the black matrix 202 of the color filter substrate 200 close to the array substrate 100 and the second spacer layer 420 may be in direct contact with the black matrix 202. The first spacer layer 410 of the array substrate 100 is correspondingly connected with the second spacer layer 420 of the color filter substrate 200.

In an exemplary implementation, a section of the first spacer layer 410 in a direction perpendicular to the first base substrate includes a regular trapezoid, and a section of the second spacer layer 420 in the direction perpendicular to the first base substrate includes an inverted trapezoid.

An embodiment of the present disclosure further provides a display device including the array substrate described in any one of above embodiments.

An embodiment of the present disclosure further provides a manufacturing method for an array substrate, including: forming multiple first wires and multiple second wires on a base substrate, the first wires extending in a first direction and the second wires extending in a second direction, the first wires and the second wires intersecting with each other to define multiple sub-pixels arranged in an array, each of the sub-pixels including at least one transistor, and the first direction and the second direction intersecting with each other; and forming a color filter layer on a side of the transistor, the color filter layer including a color filter pattern corresponding to a sub-pixel, and an orthographic projection of the color filter pattern on the base substrate covering an orthographic projection of the transistor on the base substrate.

The present disclosure further provides a display device, including the array substrate described above. The display device may be any product or component with a display function, such as a mobile phone, a tablet computer, a television, a display, a laptop computer, a digital photo frame, or a navigator, which is not limited in an embodiment of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. An array substrate, comprising:
a base substrate;
a plurality of first wires and a plurality of second wires provided on a side of the base substrate, wherein the first wires extend in a first direction and the second wires extend in a second direction, the first wires and the second wires intersect with each other to define a plurality of sub-pixels arranged in an array, each of the sub-pixels comprises at least one transistor, and the first direction and the second direction intersect with each other; and
a color filter layer, provided on a side of the transistor; wherein the color filter layer comprises a color filter pattern corresponding to a sub-pixel, and an orthographic projection of the color filter pattern on the base substrate covers an orthographic projection of the transistor on the base substrate.

2. The array substrate according to claim 1, wherein in the first direction, a portion of an orthographic projection of the color filter pattern corresponding to one sub-pixel of adjacent sub-pixels on the base substrate falls into an orthographic projection of the other sub-pixel of the adjacent sub-pixels on the base substrate.

3. The array substrate according to claim 2, wherein an orthographic projection of a second wire between the adjacent sub-pixels on the base substrate overlaps with orthographic projections of respective color filter patterns of adjacent two sub-pixels on the base substrate.

4. The array substrate according to claim 3, wherein an orthographic projection of a center line of the second wire on the base substrate overlaps with an orthographic projection of an overlapping boundary of the respective color filter patterns of the adjacent two sub-pixels on the base substrate.

5. The array substrate according to claim 3, wherein a ratio of a distance in the first direction between a center line of the second wire that is perpendicular to the base substrate and an overlapping boundary of the respective color filter patterns of the adjacent two sub-pixels to a length of the second wire in the first direction is greater than 0 and less than or equal to 0.33.

6. The array substrate according to claim 2, wherein the color filter pattern corresponding to one sub-pixel of the adjacent sub-pixels is provided with a bump on at least one side in the first direction, and an orthographic projection of the bump on the base substrate is located in an orthographic projection of the other sub-pixel of the adjacent sub-pixels on the base substrate; and
wherein a shape of the bump comprises a trapezoid.

7. (canceled)

8. The array substrate according to claim 1, wherein the color filter layer is provided on a side of the transistor close to the base substrate; or, the color filter layer is provided on a side of the transistor away from the base substrate.

9. The array substrate according to claim 1, wherein each of the sub-pixels further comprises a connection electrode connected with the at least one transistor, a first electrode provided on a side of the connection electrode away from the base substrate, and a contact hole exposing at least a portion of the connection electrode, the first electrode is connected with the connection electrode through the contact hole; the color filter layer is provided between the first electrode and the connection electrode, the color filter pattern comprises a hollowed-out region, and an orthographic projection of the contact hole on the base substrate is located in an orthographic projection of the hollowed-out region on the base substrate.

10. The array substrate according to claim 9, wherein the hollowed-out region of the color filter pattern corresponding to one sub-pixel of the adjacent sub-pixels is connected with the color filter pattern corresponding to the other sub-pixel.

11. The array substrate according to claim 10, wherein the color filter pattern corresponding to one sub-pixel of the adjacent sub-pixels is provided with a bump on at least one side in the first direction, and the bump protrudes into the hollowed-out region of the color filter pattern corresponding to the other sub-pixel.

12. The array substrate according to claim 11, wherein the contact hole of one sub-pixel of the adjacent sub-pixels has a first edge portion and a second edge portion, the first edge portion is adjacent to a bump of the color filter pattern corresponding to the other sub-pixel, and the second edge portion is adjacent to other sides of the hollowed-out region, a distance between the first edge portion and an edge of the bump in the first direction is L1, a minimum perpendicular distance between the second edge portion and the other sides of the hollowed-out region is L2, and the L1 is greater than or equal to the L2; and
wherein a ratio of the L1 to the L2 is less than or equal to 2 and greater than or equal to 1.

13. (canceled)

14. The array substrate according to claim 9, further comprising a planarization layer provided on a side of the color filter layer close to the first electrode and an insulation layer provided on a side of the planarization layer close to the first electrode, wherein the contact hole at least comprises a first via provided in the planarization layer and a second via provided in the insulation layer, an orthographic projection of the first via on the base substrate is located in an orthographic projection of the second via on the base substrate, and the orthographic projection of the second via on the base substrate is located in an orthographic projection of the connection electrode on the base substrate.

15. The array substrate according to claim 14, wherein a minimum perpendicular distance between an edge of the orthographic projection of the first via on the base substrate and an edge of the orthographic projection of the second via on the base substrate is L3, and a minimum perpendicular distance between the edge of the orthographic projection of the first via on the base substrate and an edge of the orthographic projection of the connection electrode on the base substrate is L4, and the L4 is greater than the L3; and
wherein a ratio of the L4 to the L3 is less than or equal to 2 and greater than or equal to 1.1

16. (canceled)

17. The array substrate according to claim 9, further comprising a second electrode provided on a side of the color filter layer close to the first electrode, and an insulation layer provided on a side of the second electrode close to the first electrode, wherein the first electrode is in direct contact with the insulation layer.

18. The array substrate according to claim 17, further comprising a spacer layer provided on a side of the insulation layer away from the base substrate, wherein the spacer layer is in direct contact with the insulation layer, and an orthographic projection of the first electrode on the base substrate does not overlap with an orthographic projection of the spacer layer on the base substrate; and
wherein a section of the spacer layer in a direction perpendicular to the base substrate comprises at least one of a rectangle, a regular trapezoid, and an inverted trapezoid.

19. (canceled)

20. The array substrate according to claim 1, wherein the transistor comprises a gate provided on the base substrate, a gate insulation layer provided on a side of the gate away from the base substrate, an active layer provided on a side of the gate insulation layer away from the base substrate, and a first pole and a second pole provided on a side of the active layer away from the base substrate, and the first pole and the second pole are connected by the active layer.

21. A display device, comprising the array substrate according to claim 1.

22. The display device according to claim 21, further comprising a color filter substrate provided opposite to the array substrate, wherein the color filter substrate comprises a black matrix, and an orthographic projection of the black matrix on the base substrate does not overlap with an orthographic projection of at least a portion of the second wire on the base substrate.

23. The display device according to claim 22, further comprising a first spacer layer, wherein a side of the first spacer layer close to the array substrate is connected with the array substrate, and a side of the first spacer layer close to the color filter substrate is connected with the color filter substrate; or
further comprising a first spacer layer and a second spacer layer, wherein a side of the first spacer layer close to the array substrate is connected with the array substrate, a side of the first spacer layer away from the array substrate is connected with the second spacer layer, a side of the second spacer layer away from the array substrate is connected with the color filter substrate, a section of the first spacer layer in a direction perpendicular to the base substrate comprises a regular trapezoid, and a section of the second spacer layer in the direction perpendicular to the base substrate comprises an inverted trapezoid.

24. (canceled)

25. A manufacturing method for an array substrate, comprising:
forming a plurality of first wires and a plurality of second wires on a base substrate, wherein the first wires extend in a first direction and the second wires extend in a second direction, the first wires and the second wires intersect with each other to define a plurality of sub-pixels arranged in an array, each of the sub-pixels comprises at least one transistor, and the first direction and the second direction intersect with each other; and
forming a color filter layer on a side of the transistor, wherein the color filter layer comprises a color filter pattern corresponding to a sub-pixel, and an orthographic projection of the color filter pattern on the base substrate covers an orthographic projection of the transistor on the base substrate.
